(19) United States
(12) Patent Application Publication
(10) Pub. No.: US 2014/0224519 A1
(43) Pub. Date: Aug. 14, 2014

(54) ANTIMICROBIAL SELF-ADHESIVE LIGHT SWITCH ROCKER COVER

(71) Applicant: Libertas Copper, LLC d.b.a. Hussey Copper, Leetsdale, PA (US)

(72) Inventors: Joseph MALLAK, Chagrin Falls, OH (US); John R. LINTON, JR., Cranberry Township, PA (US); Stephanie BRICKNER, Jefferson Hills, PA (US)

(73) Assignee: Libertas Copper, LLC d.b.a. Hussey Copper, Leetsdale, PA (US)

(21) Appl. No.: 14/171,459

(22) Filed: Feb. 3, 2014

Related U.S. Application Data
(60) Provisional application No. 61/762,630, filed on Feb. 8, 2013.

(51) Int. Cl. H05K 5/03

(52) U.S. Cl. CPC H05K 5/03
USPC 174/66; 29/428; 72/362; 156/60; 424/630

(57) ABSTRACT

An antimicrobial self-adhesive switch rocker cover is disclosed. The rocker cover includes a distal end and a base end wherein the switch cover comprises a copper or copper alloy. The copper or copper alloy may include a minimum of 60% copper. The copper or copper alloy may also include a MD-Cu₂₉ antimicrobial copper or copper alloy.

### CROSS REFERENCE TO PRIOR APPLICATION

This application claims priority to and the benefit thereof from U.S. provisional patent application No. 61/762,630, filed Feb. 8, 2013, titled “Antimicrobial Self-Adhesive Light Switch Rocker Cover,” the entirety of which is hereby incorporated herein by reference.

### FIELD OF THE INVENTION

The invention relates generally to an antimicrobial switch cover, and more specifically it relates to an antimicrobial self-adhesive switch rocker cover.

### BACKGROUND OF THE INVENTION

Currently, there exists large variety of strains of antibiotic resistant virulent microbes. The microbes cause diseases such as, e.g., methicillin-resistant staphylococcus aureus (MRSA), that, if left untreated, can lead to sickness and even death. This problem is especially prevalent in settings e.g., hospital, public schools, elderly homes, and the like, where virulent microbes can easily spread among its inhabitants. There is a need to frequently sanitize and/or disinfect surfaces that people may touch. One of these high contact surface areas includes light switches such as a toggle switch.

There are several types of antimicrobial agents that are currently applied to light switches and their surrounding for which antimicrobial protection is needed. These agents may include chemical antimicrobial agents e.g., disinfectants. However, these chemical antimicrobial agents are often harmful to both the environment and the person coming into contact with them. Also, many of them can lose their antimicrobial activity within a short time period. There is also silver-based antimicrobial agent that may be used in forming switch covers. However, silver-containing microbial agents are often expensive and therefore may not be suitable for certain type of light switches. There is an unfulfilled need for a novel mechanism that protects light switches from antimicrobial agents.

### SUMMARY OF THE INVENTION

Accordingly, one aspect of the present disclosure provides an antimicrobial self-adhesive switch rocker cover. The switch cover includes a distal end and a base end wherein the switch cover comprises a copper or copper alloy.

The copper or copper alloy may include a minimum of 60% copper.

The copper or copper alloy may include a MD-Cu₂₉ antimicrobial copper or copper alloy.

The switch cover may be formed to cover an electrical switch.

The switch cover may further include a thickness of about 0.005 inches to about 0.020 inches.

The switch cover may further include a thickness that is less than 0.005 inches.

The switch cover may include a thickness that is greater than 0.020 inches.

The switch cover may include a width of about 0.263 inches at the distal end.

The switch cover may include a width of about less than 0.263 at the distal end.

The switch cover may include a width of greater than about 0.263 inches at the distal end.

The switch cover may include a height of about 0.281 inches at the distal end.

The switch cover may include a height of less than about 0.281 inches at the distal end.

The switch cover may include a height of greater than about 0.281 inches at the distal end.

The switch cover may include a width of about 0.284 inches at the base end.

The switch cover may include a width of less than about 0.284 inches at the base end.

The switch cover may include a width greater than about 0.284 inches at the base end.

The switch cover may include a height of about 0.318 inches at the base end.

The switch cover may include a height of less than about 0.318 inches at the base end.

The switch cover may include a height of greater than about 0.318 inches at the base end.

The switch cover may include a length of about 0.50 inches between an edge of the distal end and an edge of the base end.

The switch cover may include a length of less than 0.50 inches, or a length greater than 0.50 inches.

According to another aspect of the present disclosure, a method for disinfecting or killing bacteria is disclosed. The method includes providing a switch cover to a location and affixing the switch cover onto a switch portion, wherein the switch cover comprises copper or copper alloy containing a minimum of 60% copper.

The method may include applying at least one coat layer of adhesive to the switch cover and/or the switch portion to adhere the switch cover to the toggle switch portion.

The switch cover may include MD-Cu₂₉ antimicrobial copper or copper alloy.

In one aspect, a method for disinfecting for disinfecting or killing bacteria is disclosed. The method includes applying a copper layer containing a minimum of 60% copper or antimicrobial copper onto a light switch plate that surrounds a switch.

In one aspect, a method for manufacturing a switch cover is disclosed. The method includes loading a material comprising at least 60% copper or antimicrobial copper on a reel, feeding the material to a forming device, and forming the material into a finished size switch cover.

### BRIEF DESCRIPTION OF THE DRAWINGS

The accompanying drawings, which are included to provide a further understanding of the disclosure, are incorporated in and constitute a part of this specification, illustrate embodiments of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIG. 1 shows an example of a front view of a switch cover that is constructed according to the principles of the disclosure.

FIG. 2 shows an example of a side view of the switch cover of FIG. 1e.

FIG. 3 shows another example of a side view of a switch cover of FIG. 1,

FIG. 4 shows another example of a front view of a switch cover affixed to a switch, according to the principles of the disclosure.

FIG. 5 shows another example of a front view of a switch cover affixed to a dimmer switch, according to the principles of the disclosure.

FIG. 6 shows an example of a process of making a switch cover, according to the principles of the disclosure.

The present invention is further described in the detailed description that follows.

### DETAILED DESCRIPTION OF THE INVENTION

The present disclosure and the various features and advantageous details thereof are explained more fully with reference to the non-limiting examples that are described and/or illustrated in the accompanying drawings and detailed in the following attached description. It should be noted that the features illustrated in the drawings are not necessarily drawn to scale, and features of one example may be employed with other examples as the skilled artisan would recognize, even if not explicitly stated herein. Descriptions of well-known components and processing techniques may be omitted so as to not unnecessarily obscure the principles of the invention. The examples used herein are intended merely to facilitate an understanding of ways in which the invention may be practiced and to further enable those of skill in the art to practice the examples of the invention. Accordingly, the examples herein should not be construed as limiting the scope of the invention, which is defined solely by the appended claims and applicable law. Moreover, it is noted that like reference numerals represent similar parts throughout the several views of the drawings.

The terms “including”, “comprising” and variations thereof, as used in this disclosure, mean “including, but not limited to”, unless expressly specified otherwise.

The terms and “the”, as used in this disclosure, means “one or more”, unless expressly specified otherwise.

Although process steps, method steps, or the like, may be described in a sequential order, such processes and methods may be configured to work in alternate orders. In other words, any sequence or order of steps that may be described does not necessarily indicate a requirement that the steps be performed in that order. The steps of the processes or methods described herein may be performed in any order practical. Further, some steps may be performed simultaneously.

When a single device or article is described herein, it will be readily apparent that more than one device or article may be used in place of a single device or article. Similarly, where more than one device or article is described herein, it will be readily apparent that a single device or article may be used in place of the more than one device or article. The functionality or the features of a device may be alternatively embodied by one or more other devices which are not explicitly described as having such functionality or features.

An aspect of the disclosure includes a switch cover that includes a copper or copper alloy containing a minimum of 60% copper.

According to a further aspect of the disclosure, a method of manufacturing a switch cover is provided including: loading material containing at least 60% copper or antimicrobial copper on a reel, feeding the material from the reel to a forming device, forming the material into finished switch cover, and shipping the switch cover for use.

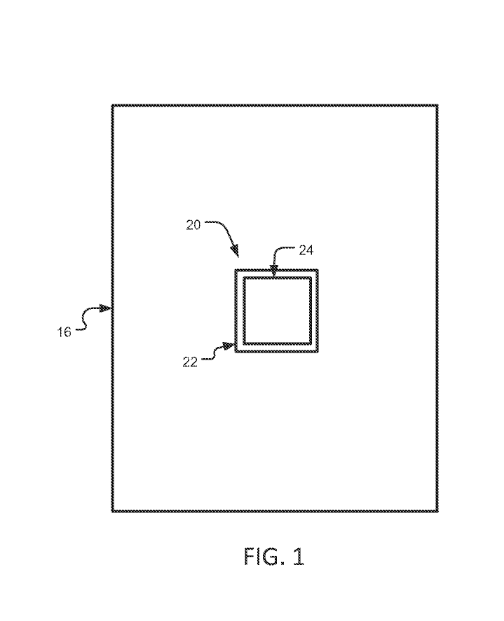

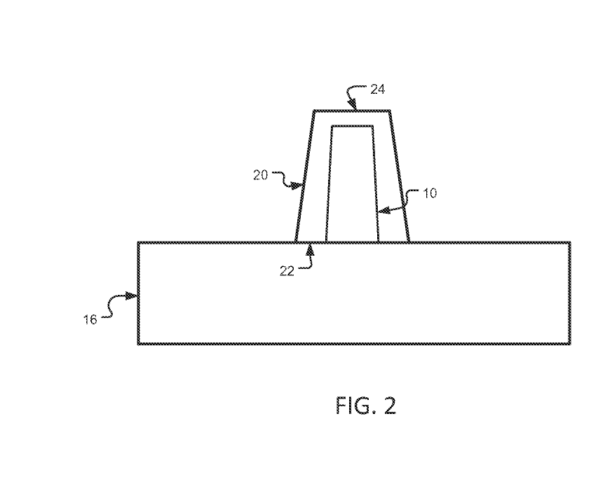

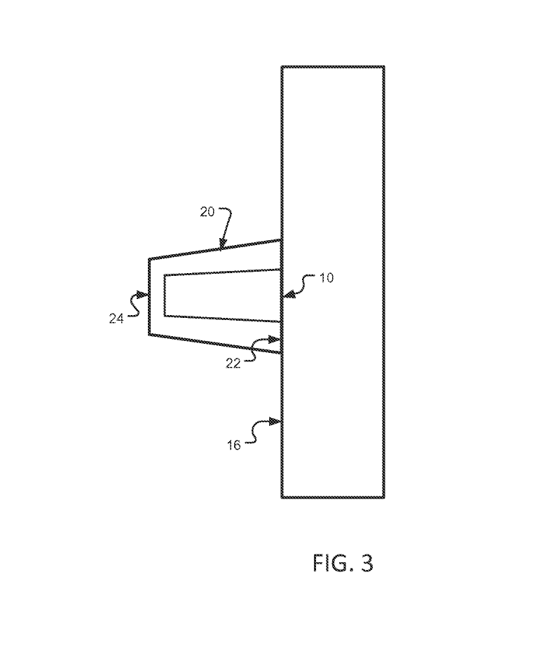

FIGS. 1-3 show an example of a switch cover that is constructed according to the principles of the disclosure. The switch cover 20 includes copper or copper alloy containing a minimum of 60% copper. For instance, the switch cover 20 may include 70%, 80%, 90%, 100%, of copper or copper alloy, or any other percentage that is equal to or greater than 60% copper. The switch cover 20 may include MD-Cu₂₉ antimicrobial copper or copper alloy. The antimicrobial copper or copper alloy should effectively kill bacteria within about two hours of exposure to the bacteria. The antimicrobial copper or copper alloy may kill about 99.9% of bacteria within about two hours of contacting (or being infected by) the bacteria. If scratched, the area where scratched will remain anti microbial. As shown, the switch cover 20 may be configured to be placed over a light switch 10 e.g., a single toggle switch, a double or more toggle switch, a single decora switch, a double or more decora switch, a dimmer switch, a rocker switch, and the like. This provides antimicrobial protection for anyone coming in contact with the switch. In one aspect of the present disclosure, the switch cover 20 may be formed as a box-like open ended cover, with multiple sides to conform to the contours of a light switch 10.

The switch cover 20 may further include a material having a temper that may range from soft to hard.

Referring to FIGS. 1-3, a switch cover 20 may include a distal end 24 and base end 22. The distal end 24 may be contacted by (e.g., a patient, doctor, visitor, janitor, and so on) to operate a switch 10 (e.g., a toggle switch). The switch cover 20 may be attached to the light switch 10 or a switch cover plate 16 by e.g., glue, a bond, an adhesive, a screw, a damp or other fastening means, a tape, or the like. The switch cover plate 16 may be attached to e.g., a wall, a door, an electrical box, and the like. In one aspect of the present disclosure, the switch cover plate 16 may include copper or copper alloy, or any other percentage that is equal to or greater than 60% copper. The switch cover plate 16 may also include MD-Cu₂₉ antimicrobial copper or copper alloy.

The switch cover 20 may have a thickness that may range, for example, from about 0.005 inches to about 0.020 inches. The switch cover 20 may also have a thickness that is less than 0.005 inches or greater than 0.020 inches. The thickness may be determined based on, e.g., customer specifications, customer requests, application demands, or the like.

In some implementations, the switch cover 20 may have a width of, e.g., about 0.263 inches at a distal end 24. The switch cover 20 may have a width of less than 0.263 inches, or a width greater than 0.263 inches at the distal end 24. The width of distal end 24 may be determined based on, e.g., customer specifications, customer requests, application demands, or the like.

In some implementations, the switch cover 20 may have a height of, e.g., about 0.281 inches at the distal end 24. The switch cover 20 may have a height of less than 0.281 inches, or a height greater than 0.281 inches distal end 24. The height of distal end 24 may be determined based on, e.g., customer specifications, customer requests, application demands, or the like.

In some implementations, the switch cover 20 may have a width of, e.g., about 0.284 inches at a base end 22. The switch cover 20 may have a width of less than 0.284 inches, or a width greater than 0.284 inches at the base end 22. In some implementations, the width of base end 22 may be determined based on, e.g., customer specifications, customer requests, application demands, or the like.

In some implementations, the switch cover 20 may have a height of, e.g., about 0.318 inches at the base end 22. The switch cover 20 may have a height of less than 0.318 inches, or a height greater than 0.318 inches at the base end 22. The height of base end 22 may be determined based on, e.g., customer specifications, customer requests, application demands, or the like.

In some implementations, the switch cover 20 may have a length of, e.g., about 0.50 inches between an edge of the distal end 24 and an edge of the base end 22 of the switch cover. The switch cover 20 may have a length of less than 0.50 inches, or a length greater than 0.50 inches. The length may be determined based on, e.g., customer specifications, customer requests, application demands, or the like.

The switch cover 20 may further have different configurations that are constructed to match switches available on the market or found in existing building structures, so that the switch covers 20 may be placed over and affixed to the toggle switches.

The switch cover 20 may also be provided or packaged with an adhesive (e.g., a glue pack, a bond, chemical adhesive, biological adhesive, a tape, or the like), which the user may use to apply an adhesive coat (or layer) to the switch cover 20 and/or a surface of an existing switch to adhere the switch cover to the switch.

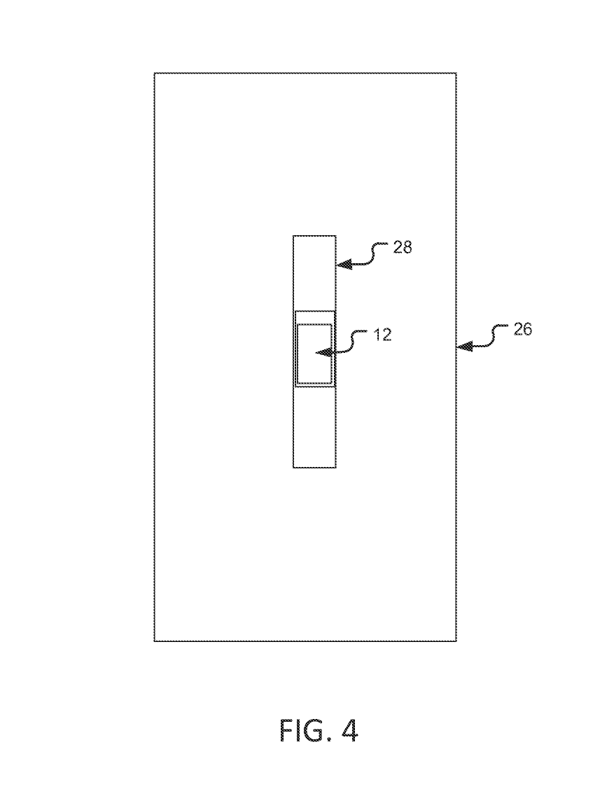

FIG. 4 shows another example of a front view of a switch cover 12 affixed to a switch according to the principles of the disclosure. As shown, a switch cover 12 may be placed over a switch (e.g., toggle switch, a slide switch, a rocker switch, or the like) and attached by an adhesive pack e.g., a glue pack, a bond, chemical adhesive, biological adhesive, a tape, and the like. The adhesive pack may be applied to the switch cover 12 and/or the surface of the switch. Alternatively, the switch cover 12 and the switch may also be attached to each other via fastening mechanism e.g., fastener, clamp, screw, and the like. The attachment of switch cover 12 and the switch may result in the switch cover 12 surrounding the switch 10 possibly with an unfilled space 28 between the switch cover 12 and a switch cover plate 26. The unfilled space 28 may also be protected by a barrier (not shown) that may include copper or copper alloy with at least 60% copper. The unfilled space 28 may also include MD-Cu₂₉ antimicrobial copper or copper alloy. Alternatively, the copper, copper alloy, or MD-Cu₂₉ may be applied to the unfilled space 28 which can be e.g., a plastic, a carbon fiber, a ceramic, a glass, and the like.

The switch cover 12 may include copper or copper alloy containing a minimum of 60% copper. For instance, the switch cover 12 may include 70%, 80%, 90%, 100%, of copper or copper alloy, or any other percentage that is equal to or greater than 60% copper. The switch cover 12 may include MD-C antimicrobial copper or copper alloy. The antimicrobial copper or copper alloy should effectively kill bacteria within about two hours of exposure to the bacteria. The antimicrobial copper or copper alloy may kill about 99.9% of bacteria within about two hours of contacting (or being infected by) the bacteria.

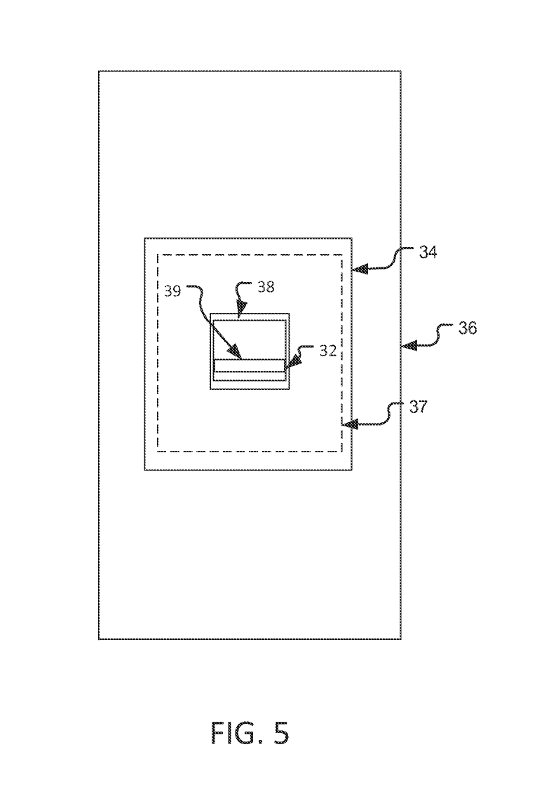

FIG. 5 shows another example of a front view of a switch cover affixed to a switch according to the principles of the disclosure. As shown, a switch cover 39 may be placed over a dimmer switch 32. The switch cover 39 and the dimmer switch 32 may be attached to one another by an adhesive e.g., a glue pack, a bond, chemical adhesive, biological adhesive, a tape, or the like. The adhesive may be applied to the switch cover 39 and/or the surface of the dimmer switch 32. The switch cover 39 and the dimmer switch 32 may also be attached to each other via fastening mechanism e.g., fastener, clamp, screw, or the like. The attachment of switch cover 39 and the dimmer switch 32 results in the switch cover 39 surrounding the dimmer switch 32. In some applications, an unfilled space 38 may also include a barrier (not shown) of copper or copper alloy with at least 60% copper. The unfilled space 38 may also include a barrier MD-Cu₂₉ antimicrobial copper or copper alloy.

The switch cover 39 may comprise copper or copper alloy containing a minimum of 60% copper. For instance, the switch cover 39 may include 70%, 80%, 90%, 100%, of copper or copper alloy, or any other percentage that is equal to or greater than 60% copper. The switch cover 39 may include MD-Cu₂₉ antimicrobial copper or copper alloy. The antimicrobial copper or copper alloy should effectively kill bacteria within about two hours of exposure to the bacteria. The antimicrobial copper or copper alloy may kill about 99.9% of bacteria within about two hours of contacting (or being infected by) the bacteria.

FIG. 5 also illustrates an optional switch housing cover 37 that may be configured to cover a switch housing plate 34. The switch housing cover 37 may be configured to approximately mirror the dimensions of a switch housing plate 34, which may have a distal end and a base end. The switch housing plate 34 is typically used to protect users form the electrical wiring in an electrical box. The switch housing cover 37 may comprise copper or copper alloy containing a minimum of 60% copper. For instance, the switch housing cover 37 may include 70%, 80%, 90%, 100%, of copper or copper alloy, or any other percentage that is equal to or greater than 60% copper. The switch housing cover 37 may include MD-Cu₂₉ antimicrobial copper or copper alloy. The antimicrobial copper or copper alloy should effectively kill bacteria within about two hours of exposure to the bacteria. The antimicrobial copper or copper alloy may kill about 99.9% of bacteria within about two hours of contacting (or being infected by) the bacteria.

The switch housing cover 37 may also be provided or packaged with an adhesive (e.g., a glue pack, a bond, chemical adhesive, biological adhesive, a tape, or the like), which the user may use to apply an adhesive coat (or layer) to the switch housing cover 37 and/or a surface of an existing switch housing plate 34 to affixed the switch housing cover 37 to the switch housing plate 34.

According to a further aspect of the disclosure, a method is provided for disinfecting or killing bacteria in areas that may involve contact with the bacteria. The method may include providing a switch cover to a location; applying an securing mechanism to the switch cover; aligning, overlaying, and affixing the switch cover to a toggle switch, wherein the switch cover may comprise copper or copper alloy containing a minimum of 60% copper. The switch cover may comprise MD-Cu₂₉ antimicrobial copper or copper alloy. The antimicrobial copper or copper alloy should effectively kill species of bacteria within, e.g., about two hours, or less (or more) of contact with the bacteria.

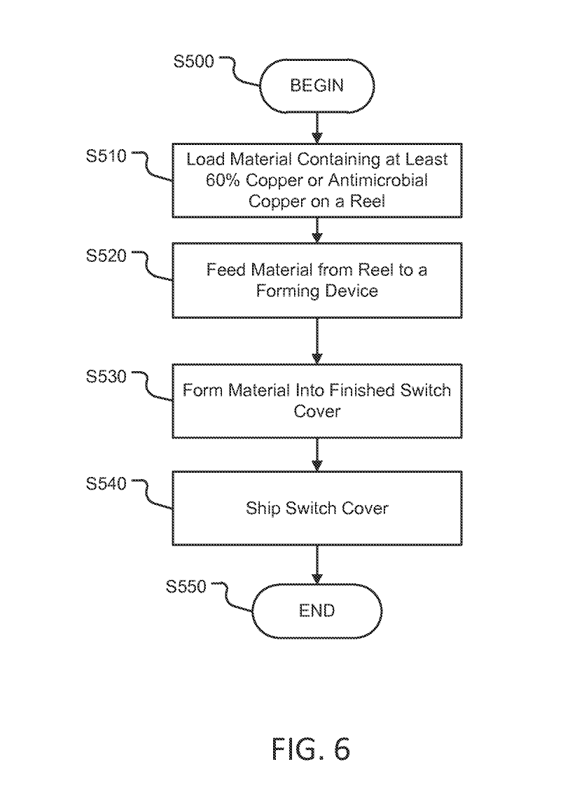

FIG. 6 shows an example of a process for manufacturing a switch cover according to the principles of the disclosure. The process includes: loading a material comprising at least 60% copper or antimicrobial copper on a reel (Step 510); feeding the material to a punch press (Step 520); and forming (e.g., stamping, cutting, etc.) the material into a finished size switch cover (Step 530). The finished switch cover may be packaged and/or shipped to, e.g., a customer (Step 540).

While the invention has been described in terms of exemplary embodiments, those skilled in the art will recognize that the invention can be practiced with modifications in the spirit and scope of the appended dams. These examples given above are merely illustrative and are not meant to be an exhaustive list of all possible designs, embodiments, applications or modifications of the invention.

What is claimed:

1. A switch cover comprising:
a distal end; and
a base end;
wherein the switch cover comprises a copper or copper alloy.

2. The switch cover according to claim 1, wherein the copper or copper alloy comprises a minimum of 60% copper.

3. The switch cover according to claim 1, wherein the copper or copper alloy comprises a MD-Cu₂₉ antimicrobial copper or copper alloy.

4. The switch cover according to claim 1, wherein the switch cover is formed to cover an electrical switch.

5. The switch cover according to claim 1 wherein the switch cover has a thickness of about 0.005 inches to about 0.020 inches.

6. The switch cover according to claim 1, wherein the switch cover has a thickness that is less than 0.005 inches.

7. The switch cover according to claim 1, wherein the switch cover has a thickness that is greater than 0.020 inches.

8. The switch cover according to claim 1, wherein the switch cover has a width of about 0.263 inches at the distal end.

9. The switch cover according to claim 1, wherein the switch cover has a width of about less than 0.263 at the distal end.

10. The switch cover according to claim 1, wherein the switch cover has a width of greater than about 0.263 inches at the distal end.

11. The switch cover according to claim 1, wherein the switch cover has a height of about 0.281 inches at the distal end.

12. The switch cover according to claim 1, wherein the switch cover has has a height of less than about 0.281 inches at the distal end.

13. The switch cover according to claim 1, wherein the switch cover has a height greater than about 0.281 inches at the distal end.

14. The switch cover according to claim 1, wherein the switch cover has a width of about 0.284 inches at the base end.

15. The switch cover according to claim 1, wherein the switch cover has a width of less than about 0.284 inches at the base end.

16. The switch cover according to claim 1, wherein the switch cover has a width greater than about 0.284 inches at the base end.

17. The switch cover according to claim 1, wherein the switch cover has a height of about 0.318 inches at the base end.

18. The switch cover according to claim 1, wherein the switch cover has a height of less than about 0.318 inches at the base end.

19. The switch cover according to claim 1, wherein the switch cover has a height greater than about 0.318 inches at the base end.

20. The switch cover according to claim 1, wherein the switch cover has a length of about 0.50 inches between an edge of the distal end and an edge of the base end.

21. The switch cover according to claim 1, wherein the switch cover has a length of less than 0.50 inches, or a length greater than 0.50 inches.

22. A method for disinfecting or killing bacteria comprising:
providing a switch cover to a location; and
affixing the switch cover onto a switch portion, wherein the switch cover comprises copper or copper alloy containing a minimum of 60% copper.

23. The method according to claim 22 further comprising:
applying at least one coat layer of adhesive to the switch cover and/or the switch portion to adhere the switch cover to the toggle switch portion.

24. The method according to claim 22 wherein the switch cover comprises MD-Cu₂₉ antimicrobial copper or copper alloy.

25. A method for disinfecting or killing bacteria comprising:
applying a copper layer containing a minimum of 60% copper or antimicrobial copper onto a light switch plate that surrounds a switch.

26. A method for manufacturing a switch cover comprising:
loading a material comprising at least 60% copper or antimicrobial copper on a reel;
feeding the material to a forming device; and
forming the material into a finished size switch cover.
